(19) United States
(12) Patent Application Publication
(10) Pub. No.: US 2025/0273931 A1
(43) Pub. Date: Aug. 28, 2025

(54) LASER APPARATUS, METHODS, AND APPLICATIONS

(71) Applicant: Xuan Sun, Pittsford, NY (US)

(72) Inventor: Xuan Sun, Pittsford, NY (US)

(21) Appl. No.: 19/042,315

(22) Filed: Jan. 31, 2025

Related U.S. Application Data
(60) Provisional application No. 63/557,900, filed on Feb. 26, 2024.
(60) Provisional application No. 63/634,994, filed on Apr. 17, 2024.

(51) Int. Cl. H01S 5/12; H01S 5/065; H01S 5/14

(52) U.S. Cl. CPC H01S 5/1234; H01S 5/0653; H01S 5/142

(57) ABSTRACT

Laser apparatus and control methods providing mode hop-free tuning of the lasing wavelength (frequency) over a broad region of, and possibly, the entire gain bandwidth of the gain medium. Broadly, the apparatus and method incorporate opposite dispersion to compensate the wavelength-dependent group delay and group-velocity dispersion inside a laser cavity for broadband mode-hop free wavelength tuning.

### RELATED APPLICATION DATA

The instant application claims priority to US provisional application Ser. No. 63/557,900 filed Feb. 26, 2024 and to US provisional application Ser. No. 63/634,994 filed Apr. 17, 2024, the subject matters of which are incorporated by reference in their entireties to the fullest extent allowed by law.

### FIELD OF THE EMBODIMENTS

Embodiments and aspects pertain most generally to the field of laser science, more particularly to laser apparatus, methods, and applications, and most particularly to laser apparatus and associated control methods enabling mode hop-free tuning over a broad band of the gain bandwidth of the laser gain medium, and applications.

### BACKGROUND

Wavelength tunable narrow-linewidth semiconductor lasers underlie many critical applications including, but not limited to, optical communication, LiDAR, atomic and optical clocks, spectroscopic sensing, optical coherence tomography, and metrology. A tunable narrow-linewidth semiconductor laser is typically an external cavity diode laser (ECDL) in which a low-loss external laser cavity supports narrow-linewidth laser operation whose lasing wavelength is selected and tuned by a narrow-band optical filter embedded in the laser cavity. An ECDL can be constructed in free space by discrete optical components in which broadband wavelength tuning is realized by mechanically rotating an optical grating together with other known optical components to change the selected lasing wavelength. Such a free-space ECDL is bulky and its wavelength tuning is slow, susceptible to external mechanical perturbations, and generally unsuitable for many applications in practical environments. On-chip tunable ECDLs resolve this issue by integrating all the laser cavity components on a chip-scale platform, providing significant advantages of size, weight, power consumption, and cost. In an on-chip integrated ECDL, broadband wavelength tuning is generally realized via the Vernier effect between a pair of sampled gratings, superstructure gratings, or double-/multi-ring microresonators inside the laser cavity. However, continuous wavelength tuning over a broad spectral band without laser mode hopping is a non-trivial issue. This is due to the difficulty in maintaining the mode number of the lasing mode during the wavelength tuning. Although Vernier wavelength tuning structures can tune the wavelength over a broad spectral range, they do not support mode-hop-free (MHF) operation. In an on-chip integrated laser, MHF wavelength tuning requires a sophisticated coordinated tuning and control of the Vernier wavelength tuning structures together with a phase-shifter section embedded in the laser cavity. This approach, however, remains challenging to realize MHF tuning over a broad band. Moreover, it also requires tremendous power to tune the phase shifter section. To date, the broadest MHF tuning range of an integrated laser is limited to only ˜3 nm in the telecom band around 1550 nm, which already requires a significant power of up to about 1 Watt to tune the thermo-optic phase shifter. The inventor has recognized that laser apparatus and methods which enable broadband MHF wavelength tuning essentially over the entire laser gain bandwidth for an on-chip integrated laser would provide solutions for the known shortcomings in the art and be highly advantageous for broad and beneficial applications. The aspects and embodiments described below and in the appended claims offer said solutions.

### SUMMARY

An aspect is a method for controlling a laser apparatus to provide mode hop-free (MHF) tuning of the lasing wavelength over a broad and possibly the entire gain bandwidth of the laser gain medium. According to a non-limiting, exemplary embodiment the method includes the steps of providing a laser apparatus having a gain section having a length, L_{g}, that provides optical gain over a gain bandwidth, a passive waveguide section having a length, Lₚ, that forms an external laser cavity, an optical-filter section that selects and controls a lasing frequency ω, and a phase compensation section adapted to assist the lasing-frequency tuning, wherein the gain section, the passive waveguide section, and the optical filter section introduce respective phase shifts of φ_{g}(ω)=β_{g}(ω)L_{g}, φₚ(ω)=βₚ(ω)Lₚ, φ_{f}(ω)=2M_{F}π (where M_{f} is an integer) at the lasing frequency ω, where β_{g} and βₚ are the propagation constants for the respective gain and passive waveguide sections, further wherein the phase compensation section is adapted to introduce a phase shift φ_{c}(ω) that satisfies the condition

$$[ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] - \frac{π}{2} \leq {φ}_{c} ( ω ) - {φ}_{c} ( {ω}_{0} ) \leq [ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] + \frac{π}{2} ,$$

where ω₀ is a reference optical frequency within a tuning frequency range of the gain bandwidth, whereby said method enables mode hop-free (MHF) tuning of the laser over the gain bandwidth. According to various alternative exemplary and illustrative non-limiting embodiments, the method may include the following additional steps, limitations, characteristics, or features singly or in combination(s) as a person skilled in the art would understand:
   further wherein the phase compensation section satisfies the condition:

$$- \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] + … \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] + … ,$$

where

$$Δω = ω - {ω}_{0} , {β}_{j}^{( n )} = \frac{{d}^{n} {β}_{j}}{d {ω}^{n}} ( j = g , p )$$

is the nth-order dispersion coefficient at ω₀;
   further comprising designing the phase compensation section to compensate for both the first-order and second-order dispersion of the gain and passive waveguide sections according to:

$$- \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] ;$$

further comprising designing the passive waveguide section such that it has a group-velocity dispersion that compensates for the group-velocity dispersion of the gain section, with [β_{g}⁽²⁾L_{g}+βₚ⁽²⁾Lₚ]=0; and designing the phase compensation section to have a linear frequency-dependent phase shift as

$$- \frac{π}{2} - Δω [ {β}_{g}^{( 1 )} {L}_{g} + {β}_{p}^{( 1 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] ;$$

further comprising designing the phase compensation section to compensate for both the first-order and second-order dispersion of the gain and passive waveguide sections according to:

$${φ}_{c} ( ω ) - {φ}_{c} ( {ω}_{0} ) = - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] ;$$

further comprising designing the passive waveguide section such that it has a group-velocity dispersion that compensates for the group-velocity dispersion of the gain section, with [β_{g}⁽²⁾L_{g}+βₚ⁽²⁾Lₚ]=0; and designing the phase compensation section to have a linear frequency-dependent phase shift as

$${φ}_{c} ( ω ) - {φ}_{c} ( {ω}_{0} ) = - Δω [ {β}_{g}^{( 1 )} {L}_{g} + {β}_{p}^{( 1 )} {L}_{p} ] ;$$

wherein the optical-filter section is two Vernier ring resonators, Ring 1 and Ring 2, where Ring 1 has a set of optical resonances with frequencies of {ω₁ᵢ} (i=1, 2, . . . ), with a free-spectral range (FSR) of FSR1 and Ring 2 has a set of optical resonances with frequencies of {ω₂ᵢ} (i=1, 2, . . . ), with a free-spectral range (FSR) of FSR2, further comprising tuning the resonance frequency ω₁ᵢ of Ring 1 over a frequency tuning range of FSR1 with a periodic time waveform having a period of T₀; and tuning the resonance frequency ω₂ᵢ of Ring 2 with the same periodic time waveform having a period of T₀ over a frequency tuning range of FSR1 during a ramping-up time section and tuning the resonance frequency ω₂ᵢ of Ring 2 back by an amount of FSR2 during a ramping-down time section until after m periods of time the resonance of Ring 2 is tuned back by an amount of m(FSR1−FSR2)+FSR2, to be reset to the original value;
   wherein the periodic time waveforms are selected from a group including sawtooth, triangle, sinusoidal, and square waves;
      further comprising tuning the vernier ring resonators by at least one of electro-optically, thermo-optically, electromechanically, and piezoelectrically.
wherein the laser apparatus is an external-cavity distributed Bragg reflector (eDBR) laser structure wherein the optical-filter section is a narrow-band DBR filter, further comprising: tuning the center frequency of the DBR filter over a tuning range of the DBR filter by at least one of electro-optically, thermo-optically, electromechanically, and piezoelectrically.

An aspect is a laser apparatus characterized by mode hop-free (MHF) tuning of the lasing wavelength over a broad and possibly the entire gain bandwidth of the laser gain medium. According to a non-limiting, exemplary embodiment the laser apparatus includes a gain section having a length, L_{g} and a gain bandwidth; a passive waveguide section external laser cavity having a length, Lₚ, an optical-filter section adapted to select and control a lasing frequency ω; and a phase compensation section adapted to assist lasing-frequency tuning, wherein the gain section, the passive waveguide section, and the optical filter section introduce respective phase shifts of φ_{g}(ω)=β_{g}(ω)L_{g}, φₚ(ω)=βₚ(ω)Lₚ, φ_{f}(ω)=2M_{F}π (where M_{f} is an integer) at the lasing frequency ω, where β_{g} and βₚ are the propagation constants for the respective gain and passive waveguide sections, further wherein the phase compensation section is adapted to introduce a phase shift φ_{c}(ω) that satisfies the condition

$$[ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] - \frac{π}{2} \leq {φ}_{c} ( ω ) - {φ}_{c} ( {ω}_{0} ) \leq [ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] + \frac{π}{2} ,$$

where ω₀ is a reference optical frequency within a tuning frequency range of the gain bandwidth, whereby said laser apparatus is a mode hop-free (MHF) tunable laser over the gain bandwidth. According to various alternative exemplary and illustrative non-limiting embodiments, the laser apparatus may include the following additional, limitations, characteristics, or features singly or in combination(s) as a person skilled in the art would understand:
   further wherein the phase compensation section is characterized by the condition:

$$- \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] + … \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] + … ,$$

where

$$Δω = ω - {ω}_{0} , {β}_{j}^{( n )} = \frac{{d}^{n} {β}_{j}}{d {ω}^{n}} ( j = g , p )$$

is the nth-order dispersion coefficient at ω₀;
wherein the passive waveguide section is characterized by a group-velocity dispersion that compensates for the group-velocity dispersion of the gain section, with [β_{g}⁽²⁾L_{g}+βₚ⁽²⁾Lₚ]=0 and the phase compensation section is characterized by a linear frequency-dependent phase shift of

$$- \frac{π}{2} - Δω [ {β}_{g}^{( 1 )} {L}_{g} + {β}_{p}^{( 1 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] .$$

further wherein the passive waveguide section is characterized by a group-velocity dispersion that compensates for a group-velocity dispersion of the gain section, with [β_{g}⁽²⁾L_{g}+βₚ⁽²⁾Lₚ]=0; and the phase compensation section is characterized by a linear frequency-dependent phase shift as φ_{c}(ω)−φ_{c}(ω₀)=−Δω[β_{g}⁽¹⁾L_{g}+βₚ⁽¹⁾Lₚ];
wherein the phase compensation section is characterized by a phase shift compensating for both the first-order and second-order dispersion of the gain and passive waveguide sections, according to

$$- \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] ;$$

further wherein the phase compensation section is characterized by a phase shift compensating for both the first-order and second-order dispersion of the gain and passive waveguide sections, according to

$${φ}_{c} ( ω ) - {φ}_{c} ( {ω}_{0} ) = - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] ;$$

wherein the phase compensation section is a chirped Bragg grating;
   further comprising a tuning electrode operationally integrated with the chirped Bragg grating;
wherein the optical-filter section is two Vernier ring resonators, Ring 1 and Ring 2, where Ring 1 has a set of optical resonances with frequencies of {ω₁ᵢ} (i=1, 2, . . . ), with a free-spectral range (FSR) of FSR1 and Ring 2 has a set of optical resonances with frequencies of {θ₂ᵢ} (i=1, 2, . . . ), with a free-spectral range (FSR) of FSR2;
comprising an external-cavity distributed Bragg reflector (eDBR) laser structure wherein the optical-filter section is a narrow-band DBR filter;
   further comprising a tuning electrode operationally integrated with the chirped Bragg grating;
      further comprising a phase shifter disposed in the laser cavity;
wherein the gain section is a reflective semiconductor optical amplifier (RSOA), and an external cavity photonic integrated circuit (PIC) chip operationally integrated with the ROSA, comprising the optical filter in the form of at least two Vernier microring resonators, the passive waveguide sections, and the phase compensation section in the form of a chirped Bragg grating reflector end mirror having a dispersion property described by

$$- \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] ;$$

wherein the gain section is a reflective semiconductor optical amplifier (RSOA), and an external cavity photonic integrated circuit (PIC) chip operationally integrated with the ROSA, comprising the optical filter in the form of at least two Vernier microring resonators, the passive waveguide sections with a group-velocity dispersion of βₚ⁽²⁾Lₚ=−β_{g}⁽²⁾L_{g}, and the phase compensation section in the form of a chirped Bragg grating reflector end mirror having a dispersion property described by

$$- \frac{π}{2} - Δω [ {β}_{g}^{( 1 )} {L}_{g} + {β}_{p}^{( 1 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] .$$

wherein the PIC has a material platform selected from a group including silicon, silicon nitride, silicon oxide, silicon carbide, lithium niobate (LiNBO₃), lithium tantalate (LiTaO₃), potassium niobate (KNbO₃), III-V semiconductors (AlN, GaN, GaP, GaAs, AlGaAs, InP), barium titanate (BaTiO₃), lead zirconate titanate (PZT), tantalum pentoxide (Ta₂O₅), aluminum oxide (Al₂O₃), or a composite medium formed by integrating one of these materials with a dielectric material such as silicon nitride or silicon dioxide.
further comprising a tuning electrode operationally integrated with the chirped Bragg grating;
further comprising a phase shifter disposed in the laser cavity;
further comprising an end reflector, and wherein the gain element is heterogeneously integrated on the top of the external cavity waveguide structure;
   wherein the end reflector is a Sagnac mirror;
   wherein one of the end reflectors is the at least two Vernier microring resonators and the other end mirror is the chirped Bragg grating reflector.

### BRIEF DESCRIPTION OF THE DRAWINGS

FIG. 1 shows a schematic diagram of an on-chip integrated semiconductor laser structure as known in the art.

FIG. 2 shows a schematic diagram of an integrated laser structure for broadband MHF tuning according to a non-limiting, exemplary aspect.

FIG. 3 shows a schematic diagram of an integrated laser structure for broadband MHF tuning with tuning electrodes integrated with a chirped Bragg grating according to a non-limiting, exemplary aspect.

FIG. 4 shows a schematic diagram of an integrated laser structure for broadband MHF tuning with a phase shifter embedded in the laser cavity according to a non-limiting, exemplary aspect.

FIG. 5 shows a schematic diagram of an integrated laser structure for broadband MHF tuning with the gain element heterogeneously integrated on top of the external laser cavity PIC according to a non-limiting, exemplary aspect.

FIG. 6 shows a schematic diagram of an integrated laser structure for broadband MHF tuning with a heterogeneously integrated gain element and two Vernier microring resonators functioning as an end mirror according to a non-limiting, exemplary aspect.

FIG. 7 shows a schematic diagram of the resonance tuning waveforms of two Vernier ring resonators to achieve broadband MHF tuning of lasing frequency. The upper waveform (blue curve) shows the resonance tuning waveform of Ring 1, and the lower waveform (red curve) shows the resonance tuning waveform for Ring 2. In the figure, resonance frequency tuning of Ring 1 is shown to be between ω₁ᵢ−FSR1/2 and ω₁ᵢ+FSR1/2, but other tuning ranges such as between ω₁ᵢ−FSR1 and ω₁ᵢ or between ω₁ᵢ and ω₁ᵢ+FSR1 can be used as well. In the figure, FSR1 is shown to be larger than FSR2, but it is solely for illustration purpose. In practice, it can be smaller than FSR2. The curve on the bottom figure schematically shows the corresponding time dependent laser frequency tuning according to a non-limiting, exemplary aspect.

FIG. 8 shows a schematic diagram of the relative frequency positions of the resonances of the two Vernier ring resonators during resonance tuning over a time period of about one period, illustrating the resonance spectra of Ring 1 and Ring 2, respectively, according to a non-limiting, exemplary aspect.

FIG. 9 shows a schematic diagram of an eDBR integrated laser structure for broadband MHF tuning according to a non-limiting, exemplary aspect.

FIG. 10 shows a schematic diagram of an integrated eDBR laser structure for broadband MHF tuning with tuning electrodes integrated with the chirped Bragg grating according to a non-limiting, exemplary aspect.

FIG. 11 shows a schematic diagram of an integrated eDBR laser structure for broadband MHF tuning with a phase shifter embedded in the laser cavity according to a non-limiting, exemplary aspect.

FIG. 12 shows a schematic diagram of an eDBR laser structure for broadband MHF tuning, with the gain element heterogeneously integrated on top of the external laser cavity PIC according to a non-limiting, exemplary aspect.

### DETAILED DESCRIPTION OF NON-LIMITING, EXEMPLARY EMBODIMENTS

The disclosure herein below describes methods and apparatus enabling broadband MHF tuning over a broad region of the gain bandwidth and in some cases advantageously over the entire gain bandwidth.

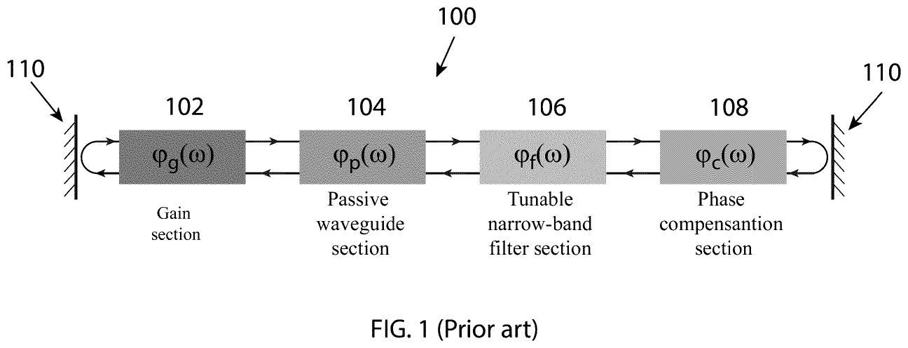

As shown in FIG. 1, an integrated laser 100 is generally composed of a gain section 102 that provides optical gain for lasing action, a passive waveguide section 104 that forms the external laser cavity (with end reflectors 110), an optical-filter section 106 for wavelength tuning and control, and a phase compensation section 108 for assisting wavelength tuning. These sections introduce a phase shift of ω_{g}(ω), ωₚ(ω), ω_{f}(ω), and ω_{c}(ω), respectively, at optical frequency ω. For the gain section 102 with a length of L_{g} and the passive waveguide section 104 with a length of Lₚ, the optical phase shifts are given by ω_{g}(ω)=β_{g}(ω)L_{g} and ωₚ(ω)=βₚ(ω)Lₚ, respectively, where β_{g} and βₚ are the propagation constants for the two sections.

The inventor has recognized that broadband MHF wavelength tuning can be achieved by a specifically designed phase compensation section whose phase shift ϕ_{c}(ω) satisfies the following condition:

$$[ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] - \frac{π}{2} \leq {φ}_{c} ( ω ) - {φ}_{c} ( {ω}_{0} ) \leq [ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] + \frac{π}{2} , \qquad ( 1 )$$

where ω₀ is a reference optical frequency within the tuning frequency range.

More specifically, the propagation constants of the gain and passive-waveguide sections can be described by

$${β}_{j} ( ω ) = {\sum }_{n = 0}^{+ ∞} \frac{{β}_{j}^{( n )}}{n !} {( Δω )}^{n} ( j = g , p ) ,$$

where βⱼ⁽ⁿ⁾ is the nth-order dispersion coefficient at ω₀, and Δω=ω−ω₀. As a result, Eq. (1) becomes

$$[ {φ}_{f} ( {ω}_{0} ) - {φ}_{f} ( ω ) ] - {\sum }_{n = 1}^{+ ∞} \frac{{( Δω )}^{n}}{n !} [ {β}_{g}^{( n )} {L}_{g} + {β}_{p}^{( n )} {L}_{p} ] - \frac{π}{2} \leq {φ}_{c} ( ω ) - {φ}_{c} ( {ω}_{0} ) \leq [ {φ}_{f} ( {ω}_{0} ) - {φ}_{f} ( ω ) ] - {\sum }_{n = 1}^{+ ∞} \frac{{( Δω )}^{n}}{n !} [ {β}_{g}^{( n )} {L}_{g} + {β}_{p}^{( n )} {L}_{p} ] + \frac{π}{2} . \qquad ( 2 )$$

On the other hand, the optical filter is generally a resonance-based filter such as distributed Bragg gratings, microresonators, or Fabry-Perot-type cavities with a phase shift of φ_{f}(w)=2M_{f}π (M_{f} is an integer). Therefore, Eq. (2) reduces to

$$- \frac{π}{2} - {\sum }_{n = 1}^{+ ∞} \frac{{( Δω )}^{n}}{n !} [ {β}_{g}^{( n )} {L}_{g} + {β}_{p}^{( n )} {L}_{p} ] \leq {φ}_{c} ( ω ) - {φ}_{c} ( {ω}_{0} ) \leq \frac{π}{2} - {\sum }_{n = 1}^{+ ∞} \frac{{( Δω )}^{n}}{n !} [ {β}_{g}^{( n )} {L}_{g} + {β}_{p}^{( n )} {L}_{p} ] . \qquad ( 3 )$$

A semiconductor gain chip typically exhibits an optical gain bandwidth in the order of ˜(10-15) THz. Within this spectral range, up to second-order dispersion is usually adequate to describe the spectral dependent phase shift of a dielectric waveguide. As a result, Eq. (3) can be approximated as

$$- \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] + … \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δω )}^{2}}{2} [ {β}_{g}^{( 2 )} {L}_{g} + {β}_{p}^{( 2 )} {L}_{p} ] + … . \qquad ( 4 )$$

Exemplary embodiments include two design strategies to achieve the claimed broadband MHF tuning:

1: Design the passive waveguide section such that its group-velocity dispersion compensates for that of the gain section, with [β_{g}⁽²⁾L_{g}+βₚ⁽²⁾Lₚ]=0. And then design the phase compensation section to have a linear frequency-dependent phase shift as

$$- \frac{π}{2} - Δω [ {β}_{g}^{( 1 )} {L}_{g} + {β}_{p}^{( 1 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] .$$

2: Design the phase compensation section to compensate for both the first-order and second-order dispersion of the gain and passive waveguide sections, as shown in Eq. (4) above.

More specific exemplary embodiments of design strategies to achieve the claimed broadband MHF tuning include:

1: Design the passive waveguide section such that its group-velocity dispersion compensates for that of the gain section, with [β_{g}⁽²⁾L_{g}+βₚ⁽²⁾Lₚ]=0. And then design the phase compensation section to have a linear frequency-dependent phase shift as

$${φ}_{c} ( ω ) - {φ}_{c} ( {ω}_{0} ) \approx - Δω [ {β}_{g}^{( 1 )} {L}_{g} + {β}_{p}^{( 1 )} {L}_{p} ] .$$

2: Design the phase compensation section to compensate for both the first-order and second-order dispersion of the gain and passive waveguide sections, as

$${φ}_{c} ( ω ) - {φ}_{c} ( {ω}_{0} ) \approx - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] .$$

In Eq. (4), the dominant effect comes from the term that is related to the linear frequency-dependent spectral phase (or equivalently, the group delay) of the gain section and the passive-waveguide section. In general, β_{g}⁽¹⁾>0 and βₚ⁽¹⁾>0. As a result, the phase compensation section is required to have a negative linear frequency-dependent spectral phase. As a reference, the phase compensation section in a conventional integrated laser is a simple phase shifter waveguide section that does not satisfy this condition and thus cannot support broadband MHF tuning.

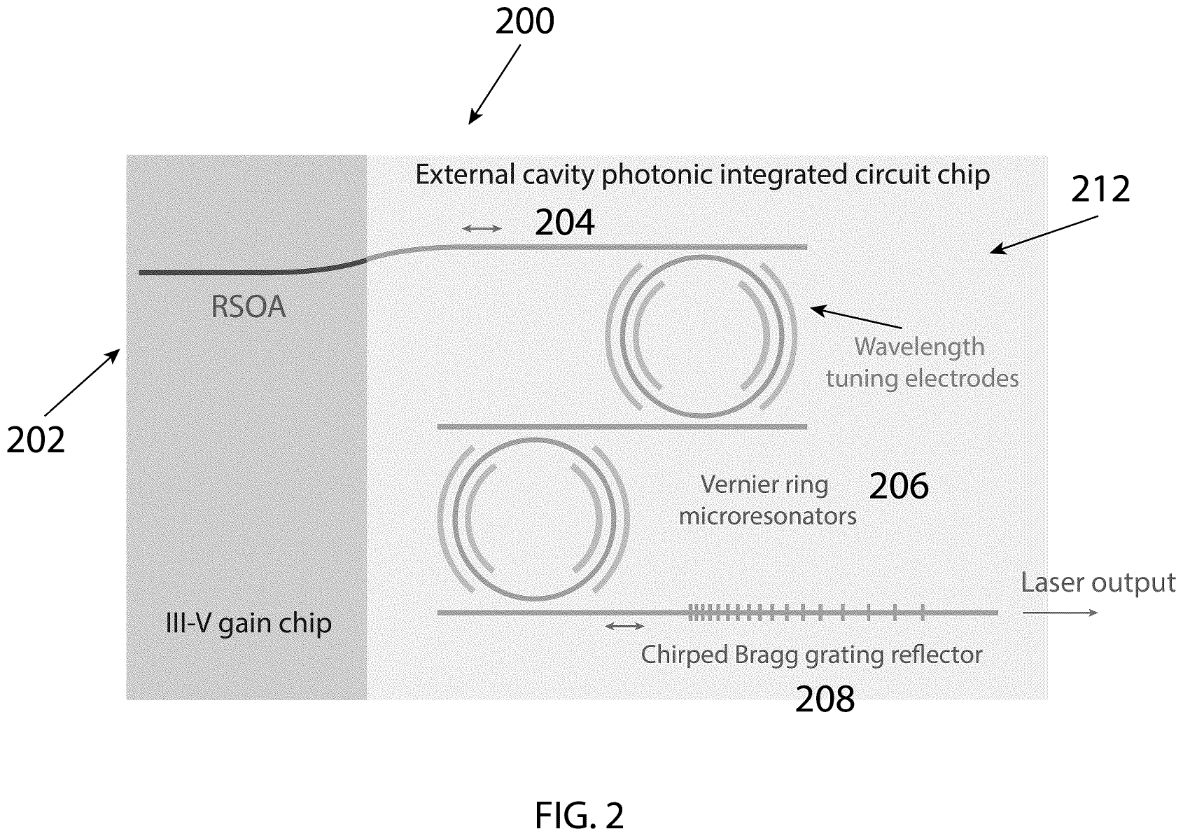

According to an illustrative embodiment, the proposed phase compensation section can be realized with a chirped distributed Bragg grating with the dispersion property given by Eq. (4). FIG. 2 shows an example of a proposed laser structure configuration 200. The laser structure is shown as a hybrid integration between a reflective semiconductor optical amplifier (RSOA) 202 and an external cavity photonic integrated circuit (PIC) chip 212. The external laser cavity consists of a pair of Vernier microring resonators 206 as the narrow-band optical filter for wavelength selection and tuning, passive waveguide section 204, and a chirped Bragg grating reflector 208 as the end mirror whose dispersion property is described by Eq. (4).

The embodied approach can be applied to different external-cavity PIC platforms, such as silicon, silicon nitride, silicon oxide, silicon carbide, lithium niobate (LiNbO₃), lithium tantalate (LiTaO₃), potassium niobate (KNbO₃), III-V semiconductors (AlN, GaN, GaP, GaAs, AlGaAs, InP), barium titanate (BaTiO₃), lead zirconate titanate (PZT), tantalum pentoxide (Ta₂O₅), aluminum oxide (Al₂O₃), or a composite medium formed by integrating one of these materials with a dielectric material such as silicon nitride or silicon dioxide.

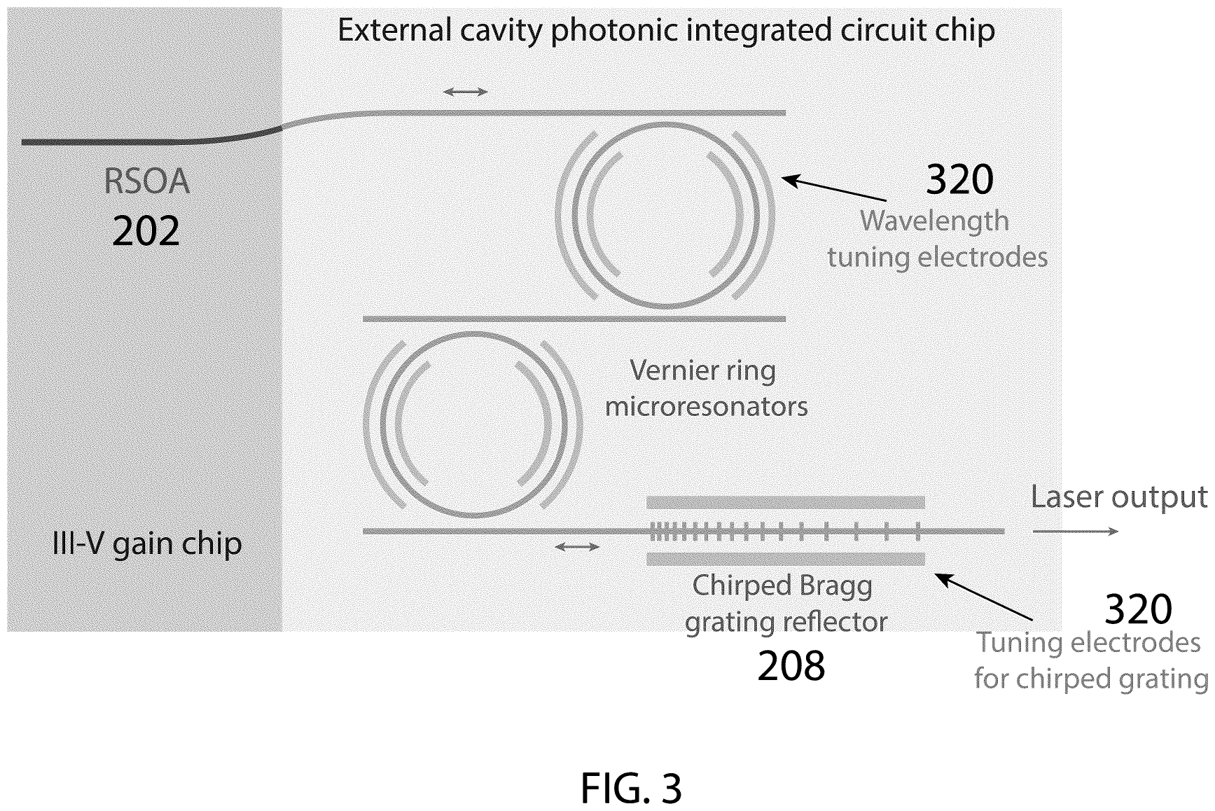

Advantageously, tuning electrodes 320 can be integrated with the chirped Bragg grating 208 for more precise wavelength tuning and for compensating certain fabrication errors, as shown in FIG. 3. The tuning mechanism can be a thermo-optic effect, electro-optic effect, electromechanical effect, or piezoelectric effect depending on the PIC material platform. For example, a thermo-optic effect can be used for silicon and silicon nitride platforms, and both thermo-optic and electro-optic effects can be used for thin-film lithium niobate and lithium tantalate platforms as a PHOSITA would understand.

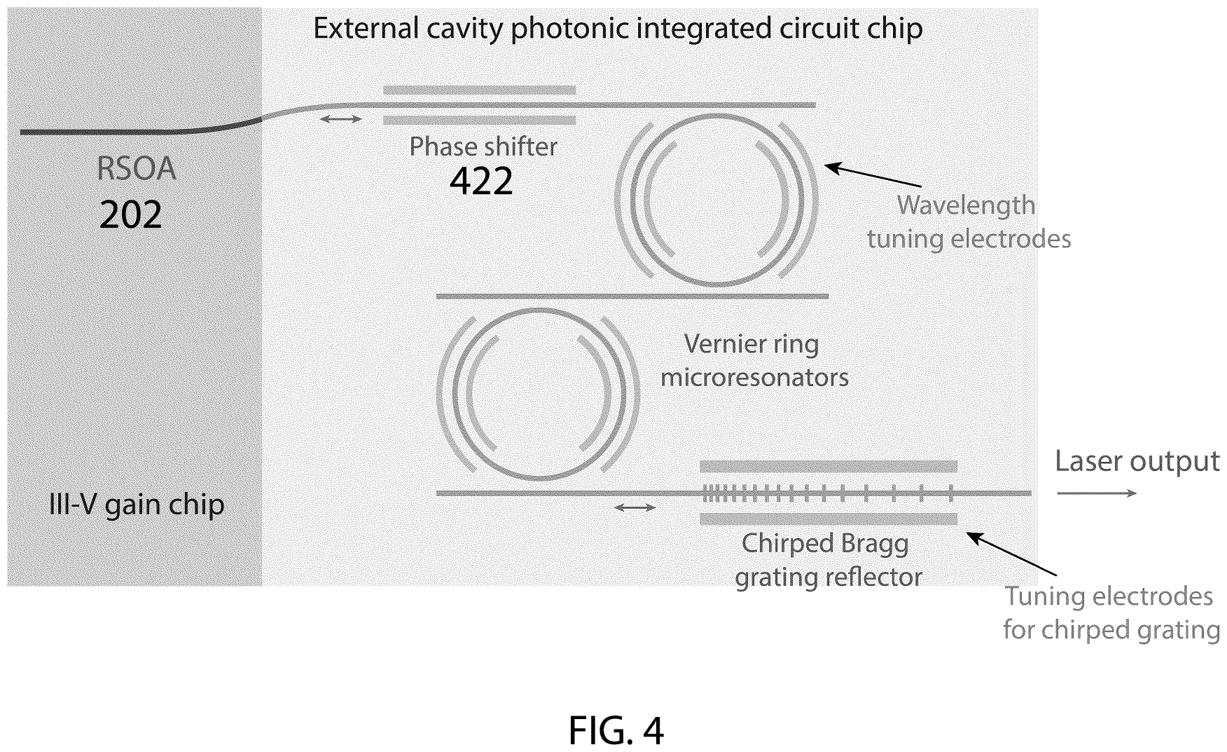

In another exemplary embodiment as shown in FIG. 4, a phase shifter 422 can be operationally disposed in the laser cavity to assist the laser operation and wavelength tuning if and when necessary.

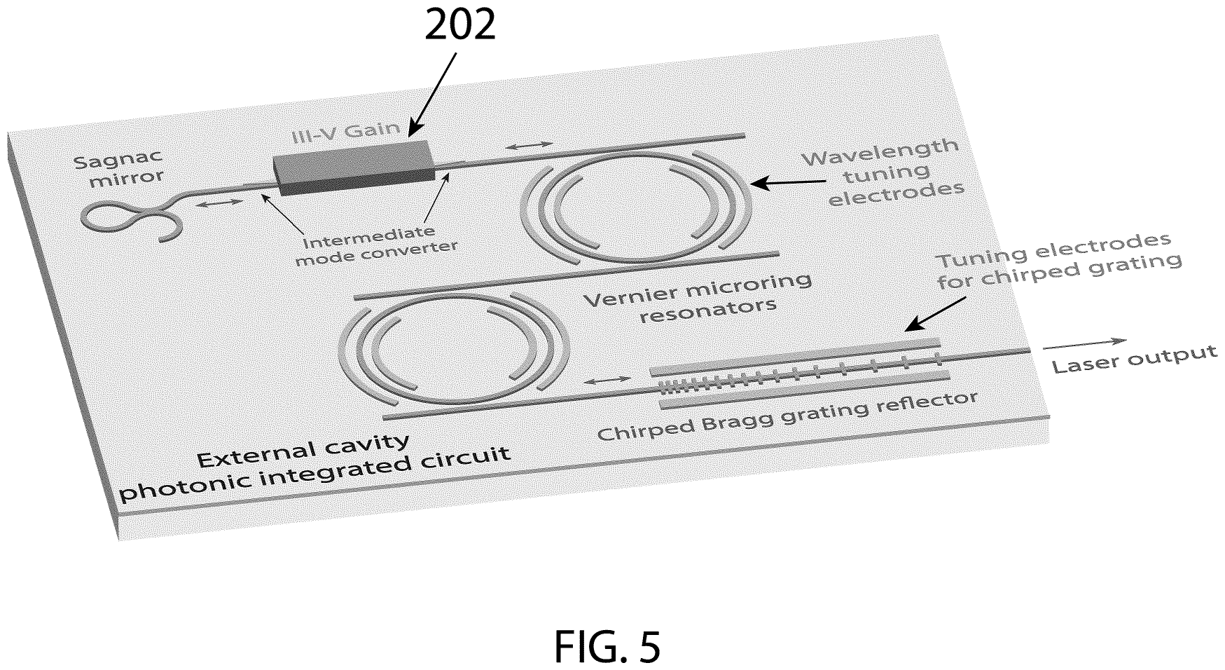

In alternative exemplary embodiments the III-V gain element can be integrated with the external laser cavity by different approaches; e.g., by edge coupling as schematically shown in FIG. 1-4 (where the III-V gain element is shown as a reflective semiconductor optical amplifier (RSOA)) 202, or, e.g., by heterogeneously integrating it on the top of the external cavity waveguide structure, as illustrated in FIG. 5.

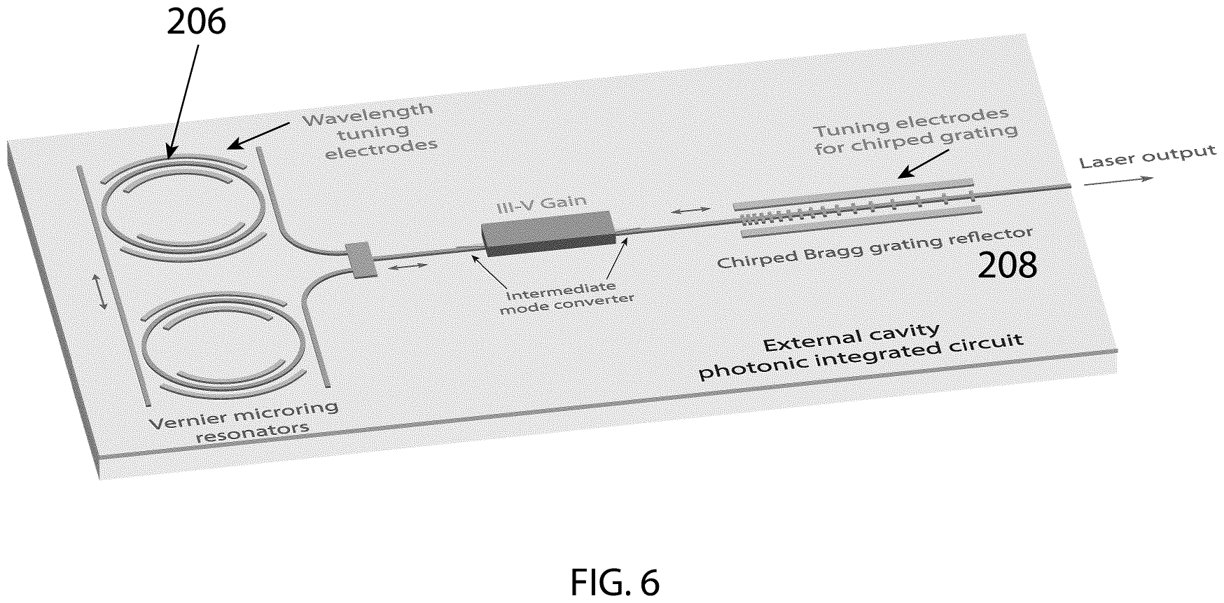

Similarly, different variations can be applied to the laser cavity structure. For example, FIG. 6 shows the Vernier microring resonators 206 used as an end mirror, and the chirped Bragg grating reflector 208 used as the other end mirror. Other types of phase compensation sections can be used as well, as long as its dispersion property satisfies Eq. (4). These same concepts and designs can be applied to fiber-based lasers and free-space lasers as well as a PHOISTA would appreciate.

In a more general sense, the optical filter section could have a certain small residual spectral dependent phase, φ_{f}(ω)−φ_{f}(ω₀)=δφ_{f}(Δω). In this case, Eq. (4) will change to

$$- \frac{π}{2} - {δφ}_{f} ( Δ ω ) - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] + … \leq {φ}_{c} ( ω ) - {φ}_{c} ( {ω}_{0} ) \leq \frac{π}{2} - {δφ}_{f} ( Δ ω ) - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] + … . \qquad ( 5 )$$

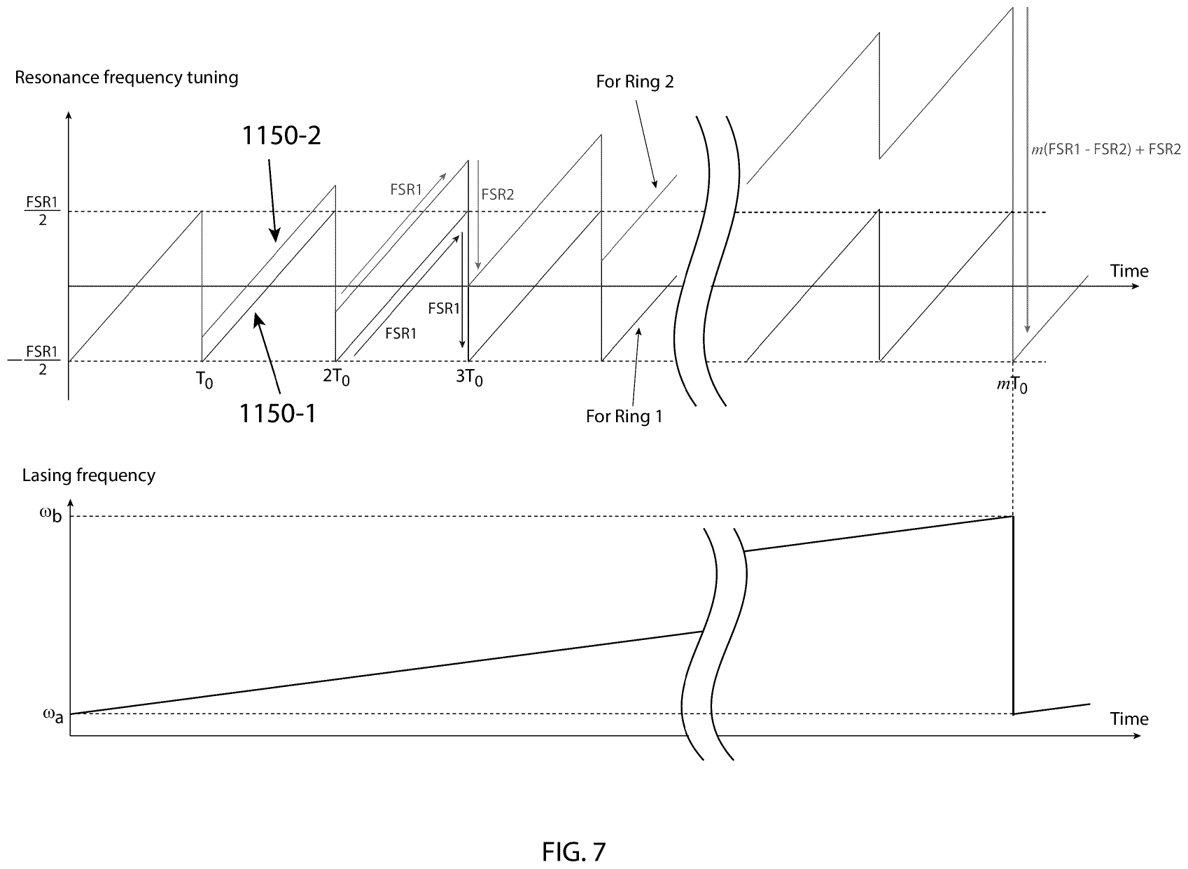

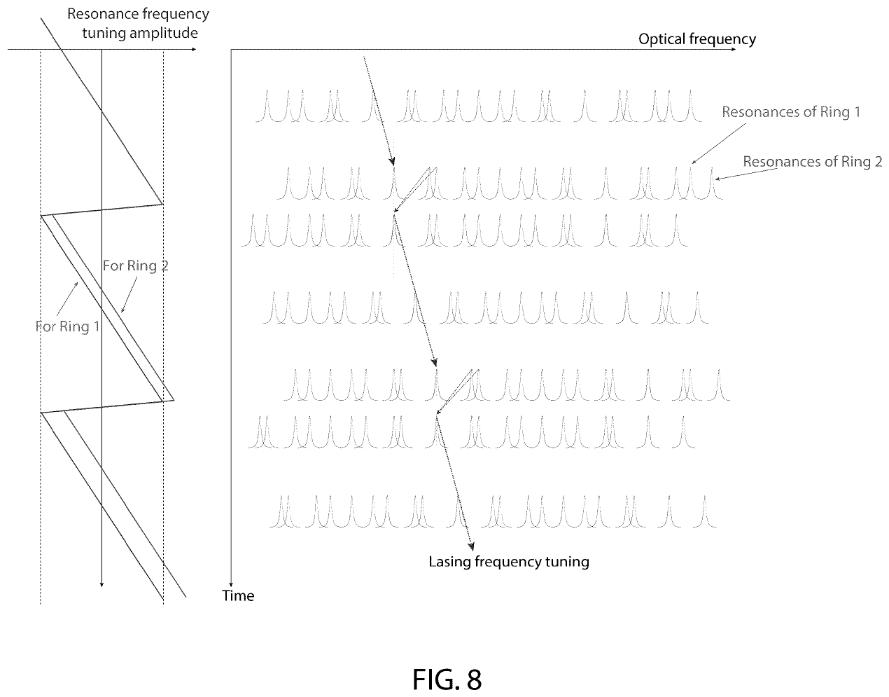

More specifically, in regard to the control method utilizing the illustrated Vernier-ring laser structure, broadband MHF tuning of the laser frequency can be realized by tuning the resonances of the two Vernier ring resonators with a time waveform as shown in FIG. 7. Assume that Ring 1 has a set of optical resonances with frequencies of {ω₁ᵢ} (i=1, 2, . . . ), with a free-spectral range (FSR) of FSR1. Assume that Ring 2 has a set of optical resonances with frequencies of {ω₂ᵢ} (i=1, 2, . . . ), with a free-spectral range (FSR) of FSR2. Two rings are tuned either electro-optically, thermo-optically, electromechanically, or piezoelectrically. The resonance frequency ω₁ᵢ of Ring 1 is tuned with a frequency tuning range of FSR1 periodically, with an exemplary sawtooth waveform 1150-1 with a period of T₀. The resonance frequency ω₂ᵢ of Ring 2 is also tuned periodically with the same sawtooth waveform 1150-2. During the ramping-up time section, the resonance is tuned by an amount of FSR1 same as Ring 1, but during the ramping-down time section it is tuned back by an amount of FSR2 instead. Then, after m periods of time, the resonance of Ring 2 is tuned back by an amount of m(FSR1−FSR2)+FSR2, to be reset to the original value. The resonance tuning is further illustrated in FIG. 8, which shows the relative frequency positions of the resonance mode spectra of the two rings when being tuned over a time duration of about one period. As a result, the lasing frequency will be tuned continuously between ωₐ and ω_{b} in the MHF fashion (FIG. 7), with a time period of mT₀. Advantageously, the embodied method does not require a coordinated tuning of a phase shifter, which not only saves a tremendous amount of power, but also significantly simplifies the control architecture. While an exemplary sawtooth waveform is used to describe the tuning process, other types of waveforms such as triangle, sinusoidal, and square can be used as well.

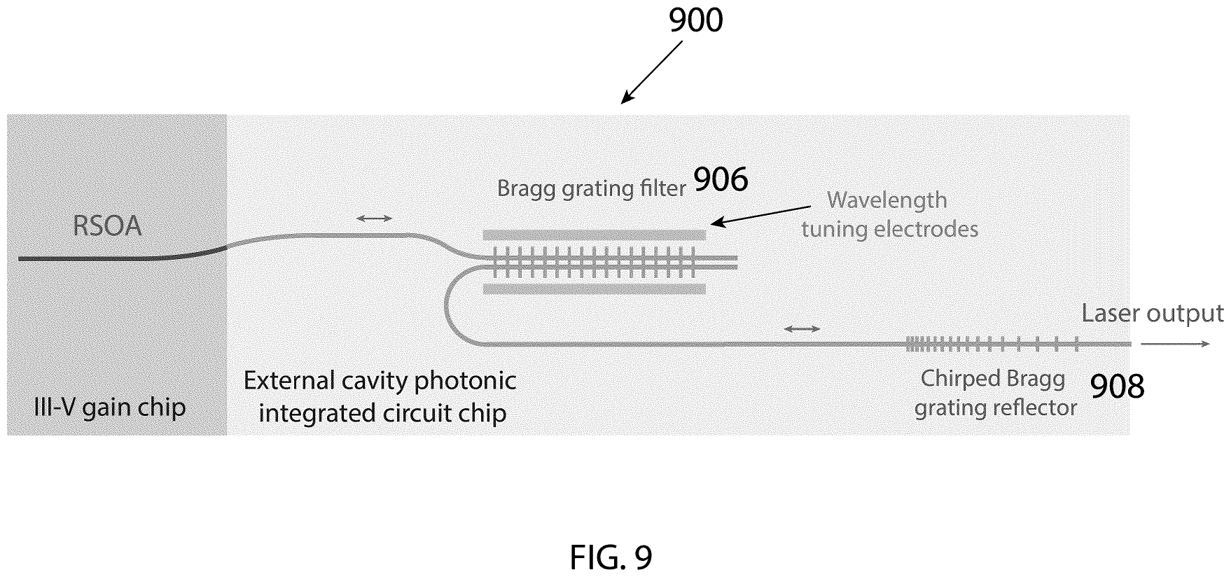

For the laser structure, in addition to the Vernier-ring-type laser structure discussed above, the embodiments can also comprise an external-cavity distributed Bragg reflector (eDBR) laser structure 900 as shown in FIG. 9. In this case, the Vernier-rings-based filter is replaced with a narrow-band DBR filter 906 for selecting the lasing frequency. By tuning the center frequency of the DBR filter, the laser can achieve MHF tuning over a broad spectral range (limited only by the tuning range of the DBR filter).

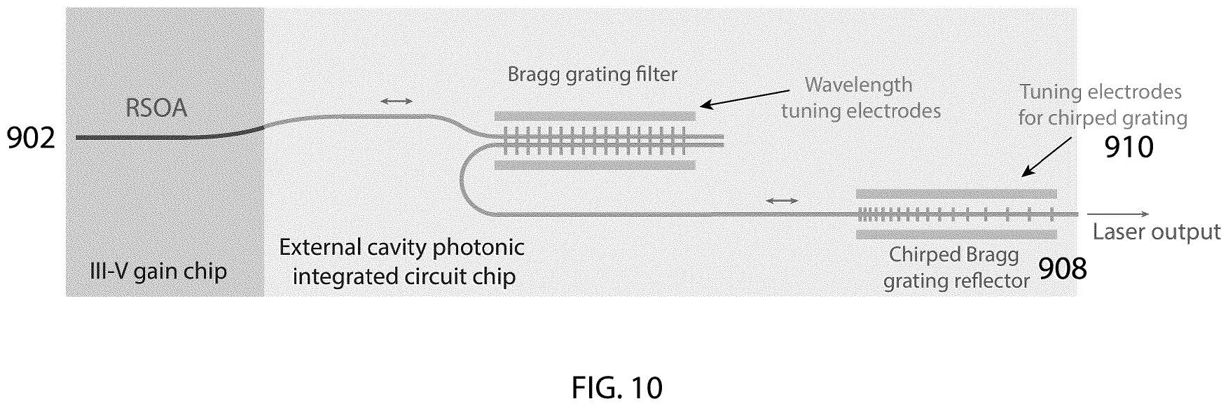

Similarly, for more precise wavelength tuning and for compensating certain fabrication errors, tuning electrodes 910 can be integrated with the chirped Bragg grating 908, as shown in FIG. 10.

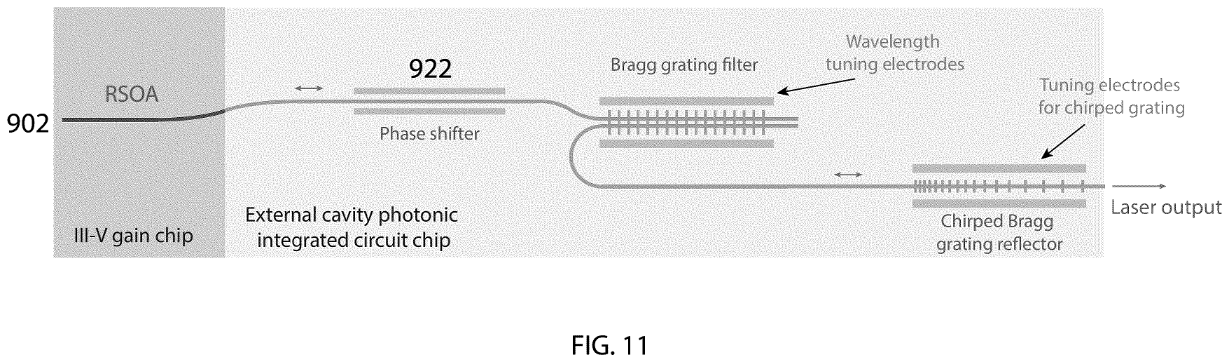

In addition, a phase shifter 922 can be added to the laser cavity as well to assist the laser operation and wavelength tuning whenever necessary, as shown in FIG. 11.

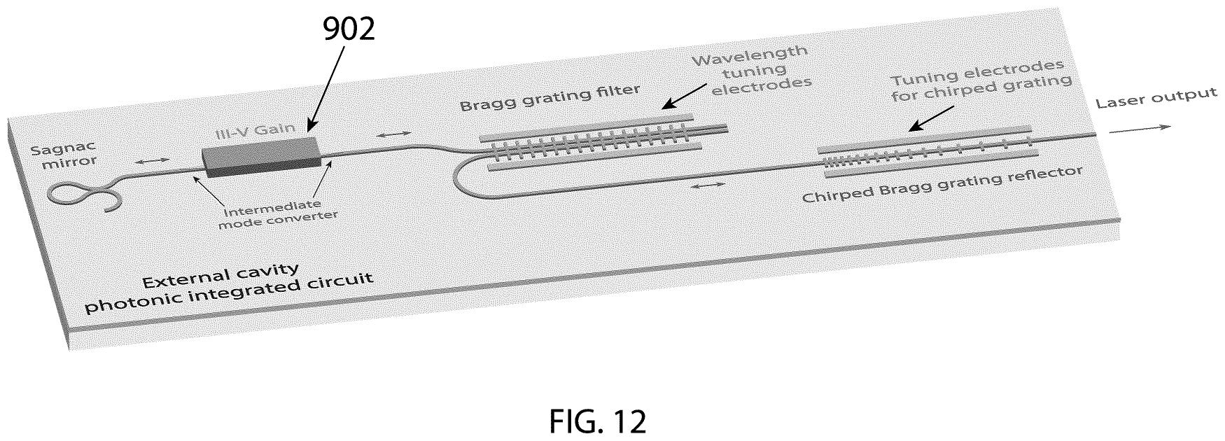

Alternatively, the III-V gain element can be integrated with the external laser cavity by different approaches, e.g., by edge coupling as schematically shown in FIGS. 9-11 (where the III-V gain element 902 is shown as a reflective semiconductor optical amplifier (RSOA)) or, e.g., by being heterogeneously integrated on the top of the external cavity waveguide structure as illustrated in FIG. 12.

It will be appreciated by those skilled in the art that other types of tunable narrow-band filters other than the illustrated DBR filter, such as Fabry-Perot filter, arrayed-waveguide grating filter, etc., can be used as well.

While various disclosed embodiments have been described above, it should be understood that they have been presented by way of example only and not as a limitation. Numerous changes to the disclosed embodiments can be made in accordance with the specification herein without departing from the spirit or scope of this specification. Thus the breadth and scope of this specification should not be limited by any of the above-described embodiments; rather, the scope of this specification should be defined in accordance with the appended claims and their equivalents.

1. A method for controlling a laser, comprising:
providing a laser apparatus comprising a gain section having a length, L_{g}, that provides optical gain over a gain bandwidth, a passive waveguide section having a length, Lₚ, that forms an external laser cavity, an optical-filter section that selects and controls a lasing frequency ω, and a phase compensation section adapted to assist the lasing-frequency tuning,
wherein the gain section, the passive waveguide section, and the optical filter section introduce respective phase shifts of φ_{g}(ω)=β_{g}(ω)L_{g}, φₚ(ω)=βₚ(ω)Lₚ, φ_{f}(ω)=2M_{F}π (where M_{f} is an integer) at the lasing frequency ω, where β_{g} and βₚ are the propagation constants for the respective gain and passive waveguide sections, further wherein the phase compensation section is adapted to introduce a phase shift φ_{c}(ω) that satisfies the condition
$$[ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] - \frac{π}{2} \leq {φ}_{c} ( ω ) - {φ}_{c} ( {ω}_{0} ) \leq [ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] + \frac{π}{2} ,$$
where ω₀ is a reference optical frequency within a tuning frequency range of the gain bandwidth,
whereby said method enables mode hop-free (MHF) tuning of the laser over the gain bandwidth.

2. The method of claim 1, further wherein the phase compensation section satisfies the condition:
$$- \frac{π}{2} - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] + … \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] + … ,$$
where
$$Δω = ω - {ω}_{0} , {β}_{j}^{( n )} = \frac{{d}^{n} {β}_{j}}{d {ω}^{n}} ( j = g , p )$$
is the nth-order dispersion coefficient at ω₀.

3. The method of claim 2, further comprising:
designing the phase compensation section to compensate for both the first-order and second-order dispersion of the gain and passive waveguide sections according to:
$$- \frac{π}{2} - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] .$$

4. The method of claim 2, further comprising:
designing the passive waveguide section such that it has a group-velocity dispersion that compensates for the group-velocity dispersion of the gain section, with [β_{g}⁽²⁾L_{g}+βₚ⁽²⁾Lₚ]=0; and
designing the phase compensation section to have a linear frequency-dependent phase shift as
$$- \frac{π}{2} - Δ ω [ {β}_{g}^{( 1 )} {L}_{g} + {β}_{p}^{( 1 )} {L}_{p} ] \leq {φ}_{c} ( ω ) - {φ}_{c} ( {ω}_{0} ) \leq \frac{π}{2} - Δ ω [ {β}_{g}^{( 1 )} {L}_{g} + {β}_{p}^{( 1 )} {L}_{p} ] .$$

5. The method of claim 3, further comprising:
designing the phase compensation section to compensate for both the first-order and second-order dispersion of the gain and passive waveguide sections according to:
$${φ}_{c} ( ω ) - {φ}_{c} ( {ω}_{0} ) \approx - Δω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] .$$

6. The method of claim 4, further comprising:
designing the passive waveguide section such that it has a group-velocity dispersion that compensates for the group-velocity dispersion of the gain section, with [β_{g}⁽²⁾L_{g}+βₚ⁽²⁾Lₚ]=0; and
designing the phase compensation section to have a linear frequency-dependent phase shift as φ_{c}(ω)−φ_{c}(ω₀)=−Δω[β_{g}⁽¹⁾L_{g}+βₚ⁽¹⁾Lₚ].

7. The method of claim 1, wherein the optical-filter section is two Vernier ring resonators, Ring 1 and Ring 2, where Ring 1 has a set of optical resonances with frequencies of {ω₁ᵢ} (i=1, 2, . . . ), with a free-spectral range (FSR) of FSR1 and Ring 2 has a set of optical resonances with frequencies of {ω₂ᵢ} (i=1, 2, . . . ), with a free-spectral range (FSR) of FSR2, further comprising:
tuning the resonance frequency ω₁ᵢ of Ring 1 over a frequency tuning range of FSR1 with a periodic time waveform having a period of T₀; and
tuning the resonance frequency ω₂ᵢ of Ring 2 with the same periodic time waveform having a period of T₀ over a frequency tuning range of FSR1 during a ramping-up time section and tuning the resonance frequency ω₂ᵢ of Ring 2 back by an amount of FSR2 during a ramping-down time section until after m periods of time the resonance of Ring 2 is tuned back by an amount of m(FSR1−FSR2)+FSR2, to be reset to the original value.

8. The method of claim 7, wherein the periodic time waveforms are selected from a group including sawtooth, triangle, sinusoidal, and square waves.

9. The method of claim 7, further comprising tuning the vernier ring resonators by at least one of electro-optically, thermo-optically, electromechanically, and piezoelectrically.

10. The method of claim 1, wherein the laser apparatus is an external-cavity distributed Bragg reflector (eDBR) laser structure wherein the optical-filter section is a narrow-band DBR filter, further comprising:
tuning the center frequency of the DBR filter over a tuning range of the DBR filter.

11. A laser apparatus comprising:
a gain section having a length, L_{g} and a gain bandwidth;
a passive waveguide section external laser cavity having a length, Lₚ;
an optical-filter section adapted to select and control a lasing frequency ω; and
a phase compensation section adapted to assist lasing-frequency tuning,
wherein the gain section, the passive waveguide section, and the optical filter section introduce respective phase shifts of φ_{g}(ω)=β_{g}(ω)L_{g}, φₚ(ω)=βₚ(ω)Lₚ, φ_{f}(ω)=2M_{F}π (where M_{f} is an integer) at the lasing frequency ω, where β_{g} and βₚ are the propagation constants for the respective gain and passive waveguide sections, further wherein the phase compensation section is adapted to introduce a phase shift φ_{c}(ω) that satisfies the condition
$$[ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] - \frac{π}{2} \leq {φ}_{c} ( ω ) - {φ}_{c} ( {ω}_{0} ) \leq [ {β}_{g} ( {ω}_{0} ) - {β}_{g} ( ω ) ] {L}_{g} + [ {β}_{p} ( {ω}_{0} ) - {β}_{p} ( ω ) ] {L}_{p} + [ {φ}_{f} ( {ω}_{0} ) - {φ}_{f} ( ω ) ] + \frac{π}{2} ,$$
where ω₀ is a reference optical frequency within a tuning frequency range of the gain bandwidth,
whereby said laser apparatus is a mode hop-free (MHF) tunable laser over the gain bandwidth.

12. The laser apparatus of claim 11, further wherein the phase compensation section is characterized by the condition:
$$- \frac{π}{2} - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] + … \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] + … ,$$
where
$$Δω = ω - {ω}_{0} , {β}_{j}^{( n )} = \frac{{d}^{n} {β}_{j}}{d {ω}^{n}} ( j = g , p )$$
where is the nth-order dispersion coefficient at ω₀.

13. The laser apparatus of claim 11, wherein:
the passive waveguide section is characterized by a group-velocity dispersion that compensates for a group-velocity dispersion of the gain section, with [β_{g}⁽²⁾L_{g}+βₚ⁽²⁾Lₚ]=0; and
the phase compensation is characterized by a linear frequency-dependent phase shift of
$$- \frac{π}{2} - Δ ω [ {β}_{g}^{( 1 )} {L}_{g} + {β}_{p}^{( 1 )} {L}_{p} ] \leq {φ}_{c} ( ω ) - {φ}_{c} ( {ω}_{0} ) \leq \frac{π}{2} - Δ ω [ {β}_{g}^{( 1 )} {L}_{g} + {β}_{p}^{( 1 )} {L}_{p} ] .$$

14. The laser apparatus of claim 11, further wherein:
the phase compensation section is characterized by a phase shift compensating for both the first-order and second-order dispersion of the gain and passive waveguide sections, according to
$$- \frac{π}{2} - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] .$$

15. The laser apparatus of claim 11, wherein the phase compensation section is a chirped Bragg grating.

16. The laser apparatus of claim 15, further comprising a tuning electrode operationally integrated with the chirped Bragg grating.

17. The laser apparatus of claim 11, wherein the optical-filter section is two Vernier ring resonators, Ring 1 and Ring 2, where Ring 1 has a set of optical resonances with frequencies of {ω₁ᵢ} (i=1, 2, . . . ), with a free-spectral range (FSR) of FSR1 and Ring 2 has a set of optical resonances with frequencies of {ω₂ᵢ} (i=1, 2, . . . ), with a free-spectral range (FSR) of FSR2.

18. The laser apparatus of claim 11, comprising an external-cavity distributed Bragg reflector (eDBR) laser structure wherein the optical-filter section is a narrow-band DBR filter.

19. The laser apparatus of claim 11, further comprising a phase shifter disposed in the laser cavity.

20. The laser apparatus of claim 11, wherein the laser cavity photonic integrated circuit (PIC) has a material platform selected from a group including silicon, silicon nitride, silicon oxide, silicon carbide, lithium niobate (LiNbO₃), lithium tantalate (LiTaO₃), potassium niobate (KNbO₃), III-V semiconductors (AlN, GaN, GaP, GaAs, AlGaAs, InP), barium titanate (BaTiO₃), lead zirconate titanate (PZT), tantalum pentoxide (Ta₂O₅), aluminum oxide (Al₂O₃), or a composite medium formed by integrating one of these materials with a dielectric material such as silicon nitride or silicon dioxide.

21. The laser apparatus of claim 20, wherein the gain section is a reflective semiconductor optical amplifier (RSOA), and an external cavity photonic integrated circuit (PIC) chip operationally integrated with the ROSA, comprising the optical filter in the form of at least two Vernier microring resonators, the passive waveguide sections, and the phase compensation section in the form of a chirped Bragg grating reflector end mirror having a dispersion property described by
$$- \frac{π}{2} - Δ ω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] \leq {φ}_{c} ( ω ) - {φ}_{c} ( {ω}_{0} ) \leq \frac{π}{2} - Δω [ {β}_{g}^{( 1 )} {L}_{g} + {β}_{p}^{( 1 )} {L}_{p} ] - \frac{{( Δ ω )}^{2}}{2} [ {β}_{g}^{( 2 )} {L}_{g} + {β}_{p}^{( 2 )} {L}_{p} ] .$$

22. The laser apparatus of claim 20, wherein the gain section is a reflective semiconductor optical amplifier (RSOA), and an external cavity photonic integrated circuit (PIC) chip operationally integrated with the ROSA, comprising the optical filter in the form of at least two Vernier microring resonators, the passive waveguide sections having a group-velocity dispersion of βₚ⁽²⁾Lₚ=−β_{g}⁽²⁾L_{g}, and the phase compensation section in the form of a chirped Bragg grating reflector end mirror having a dispersion property described by
$$- \frac{π}{2} - Δ ω [ {β}_{g}^{( 1 )} {L}_{g} + {β}_{p}^{( 1 )} {L}_{p} ] \leq {φ}_{c} ( ω ) - {φ}_{c} ( {ω}_{0} ) \leq \frac{π}{2} - Δ ω [ {β}_{g}^{( 1 )} {L}_{g} + {β}_{p}^{( 1 )} {L}_{p} ] .$$

23. The laser apparatus of claim 21, further comprising a tuning electrode operationally integrated with the chirped Bragg grating.

24. The laser apparatus of claim 21, further comprising a phase shifter disposed in the laser cavity.

25. The laser apparatus of claim 21, further comprising an end reflector, and wherein the gain element is heterogeneously integrated on the top of the external cavity waveguide structure.

26. The laser apparatus of claim 25, wherein one of the end reflectors is the at least two Vernier microring resonators and the other end mirror is the chirped Bragg grating reflector.

27. The laser apparatus of claim 22, further comprising a tuning electrode operationally integrated with the chirped Bragg grating.

28. The laser apparatus of claim 22, further comprising a phase shifter disposed in the laser cavity.

29. The laser apparatus of claim 22, further comprising an end reflector, and wherein the gain element is heterogeneously integrated on the top of the external cavity waveguide structure.

30. The laser apparatus of claim 29, wherein one of the end reflectors is the at least two Vernier microring resonators and the other end mirror is the chirped Bragg grating reflector.
